(19) United States
(12) Patent Application Publication
(10) Pub. No.: US 2016/0064513 A1
(43) Pub. Date: Mar. 3, 2016

(54) INTEGRATED CIRCUITS WITH A BOWED SUBSTRATE, AND METHODS FOR PRODUCING THE SAME

(71) Applicant: GLOBALFOUNDRIES, Inc., Grand Cayman (KY)

(72) Inventors: Ralf Richter, Radebeul (DE); Gerd Zschatzsch, Dresden (DE); Joanna Wasyluk, Dresden (DE)

(21) Appl. No.: 14/471,736

(22) Filed: Aug. 28, 2014

(51) Int. Cl. H01L 29/66; H01L 29/06; H01L 29/78; H01L 21/762; H01L 21/324

(52) U.S. Cl. CPC H01L 29/66477; H01L 21/76224; H01L 21/3247; H01L 29/78; H01L 29/0657; H01L 29/0653

(57) ABSTRACT

Integrated circuits and methods for manufacturing the same are provided. A method for manufacturing an integrated circuit includes forming a first and second STI insulator in a substrate, and bowing a substrate surface between the first and second STI insulators. A transistor is formed between the first and second STI insulators.

### TECHNICAL FIELD

The technical field generally relates to integrated circuits and methods for producing integrated circuits, and more particularly relates to integrated circuits with transistors overlying a bowed substrate and methods for producing the same.

### BACKGROUND

The majority of present day integrated circuits (ICs) are implemented by using a plurality of interconnected field effect transistors (FETs), also called metal oxide semiconductor field effect transistors (MOSFETs or MOS transistors). A MOS transistor includes a gate electrode as a control electrode overlying a semiconductor substrate. Spaced-apart source and drain regions are on opposite sides of a channel in the substrate between which a current can flow. A gate insulator is disposed between the gate electrode and the channel to electrically isolate the gate electrode from the substrate. A control voltage applied to the gate electrode controls the flow of current through the channel in the substrate underlying the gate electrode between the source and drain regions.

In many cases, a FET is positioned between two shallow trench isolation (STI) insulators, and the device width of the entire FET is the distance between the two STI insulators. Manufacturing processes include a certain amount of variability, so the distance between STI insulators does vary somewhat from one FET to another. The variability of the FET is determined by the variations of the distance between two STI insulators (ΔW, or width variation) divided by the total device width between the two STI insulators (W, or width). The device width between two STI insulators is effectively the distance along the surface of the substrate laying therebetween, and that substrate surface is flat in traditional planar FETs. The variability of FETs can be reduced by maintaining the ΔW between two STI insulators due to manufacturing variability, and increasing the device width or the effective distance between the two STI insulators. However, decreasing the size of integrated circuits is a high priority, so simply producing wider FETs is not desirable.

Accordingly, it is desirable to provide systems and methods for producing a FET with an increased effective device width between adjacent STI insulators. In addition, it is desirable to provide a FET with decreased variability without utilizing more of the substrate surface area. Furthermore, other desirable features and characteristics of the present embodiment will become apparent from the subsequent detailed description and the appended claims, taken in conjunction with the accompanying drawings and this background of the invention.

### BRIEF SUMMARY

Integrated circuits and methods of manufacturing the same are provided. In an exemplary embodiment, a method is provided for producing an integrated circuit. The method includes forming a first and second STI insulator in a substrate, and bowing a substrate surface between the first and second STI insulators. A transistor is formed between the first and second STI insulators.

In a different embodiment, a method is provided for manufacturing an integrated circuit. The method includes forming a first and second STI insulator in a substrate, where a device width is the distance between the first and second STI insulators measured along a substrate surface. The device width is increased after forming the first and second STI insulators, and a transistor is formed between the first and second STI insulators.

An integrated circuit is provided in another embodiment. The integrated circuit includes a substrate with a substrate surface. A first and second STI insulator are positioned within the substrate, where the substrate has a bowed shape between the first and second STI insulators. A transistor is positioned between the first and second STI insulators.

### BRIEF DESCRIPTION OF THE DRAWINGS

The present embodiments will hereinafter be described in conjunction with the following drawing figures, wherein like numerals denote like elements, and wherein:

FIG. 1 illustrates a perspective view of an exemplary embodiment of a substrate for an integrated circuit; and

FIGS. 2-7 illustrate, in cross sectional views along plane AA from FIG. 1, a portion of the integrated circuit and methods for its fabrication in accordance with exemplary embodiments.

### DETAILED DESCRIPTION

The following detailed description is merely exemplary in nature and is not intended to limit the various embodiments or the application and uses thereof. Furthermore, there is no intention to be bound by any theory presented in the preceding background or the following detailed description.

An integrated circuit begins with the production of first and second STI insulators, and the STI insulators are recessed to below a substrate surface. The substrate surface between the first and second STI insulators is then bowed. This increases the effective device width, because the distance between the STI insulators along a bowed surface is greater than the straight line distance between the STI insulators. The STI insulators are formed using standard techniques, so the variation in the distance between the STI insulators is consistent with traditional approaches. The substrate surface can be bowed using different techniques. For example, a cap formed by epitaxial growth can extend the substrate between the STI insulators, where the cap is grown in a bowed shape, such as by the epitaxial loading effect. In an alternate embodiment, the substrate surface is melted, such as with a gas cluster ion beam, so the substrate surface reflows and forms a bowed shape. A field effect transistor (FET) is then produced on the bowed substrate.

Referring to the exemplary embodiment illustrated in FIG. 1, an integrated circuit 10 includes a substrate 12 with a first trench 14 and a second trench 16. As used herein, the term “substrate” will be used to encompass semiconductor materials conventionally used in the semiconductor industry from which to make electrical devices. Semiconductor materials include monocrystalline silicon materials, such as the relatively pure or lightly impurity-doped monocrystalline silicon materials typically used in the semiconductor industry, as well as polycrystalline silicon materials, and silicon admixed with other elements such as germanium, carbon, and the like. Semiconductor material also includes other materials such as relatively pure and impurity-doped germanium, gallium arsenide, zinc oxide, glass, and the like. In an exemplary embodiment, the semiconductor material is a monocrystalline silicon substrate 12. The silicon substrate 12 may be a bulk silicon wafer (as illustrated) or may be a thin layer of silicon on an insulating layer (commonly known as silicon-on-insulator or SOI) that, in turn, is supported by a carrier wafer. The first and second trenches 14, 16 are formed in the substrate 12 using techniques well known to those skilled in the art.

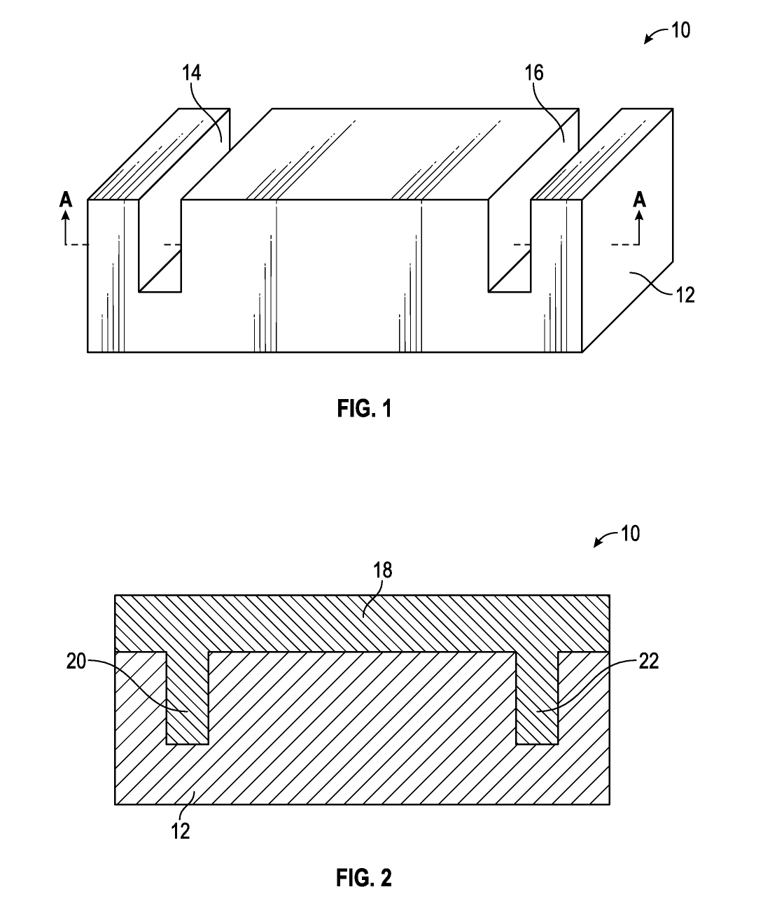

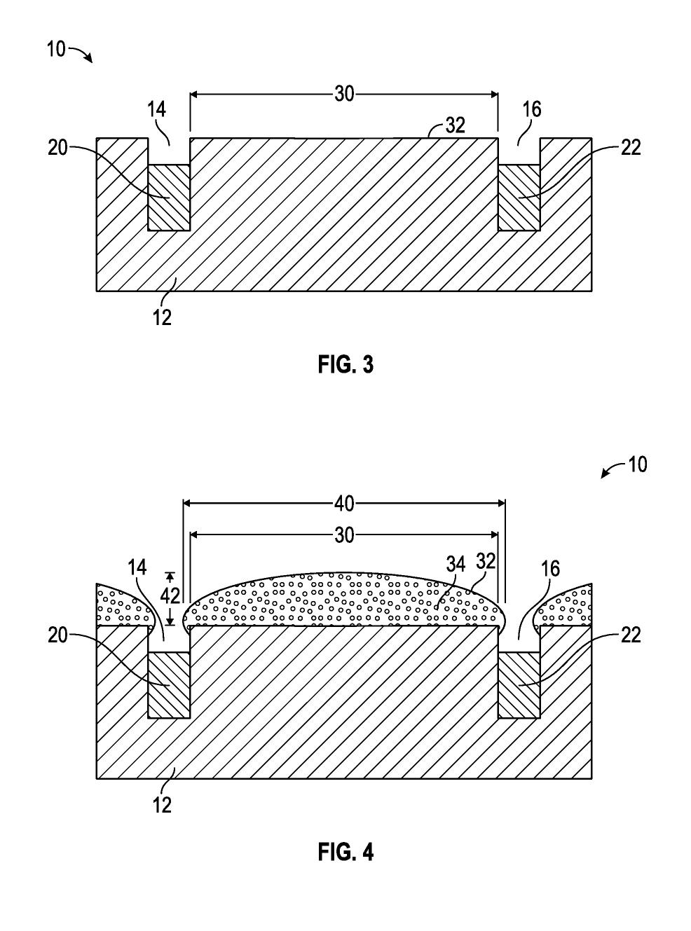

Reference is made to the exemplary embodiment illustrated in FIG. 2, where FIG. 2 is a sectional drawing taken along plane AA from FIG. 1. An STI material 18 is formed overlying the substrate 12 and within the first and second trenches 14, 16. The STI material 18 is an insulating material, such as silicon dioxide, that may be deposited by chemical vapor deposition using silane and oxygen. The STI material 18 deposited in the first and second trenches 14, 16 to produce a first STI insulator 20 and a second STI insulator 22, respectively. Chemical mechanical planarization can be used to remove excess STI material 18 overburden and to leave the first and second STI insulators 20, 22 within the substrate 12, as illustrated in an exemplary embodiment in FIG. 3 with continuing reference to FIG. 2. The first and second STI insulators 20, 22 are further recessed to a level below a substrate surface 32. The first and second STI insulators 20, 22 are recessed before the substrate surface 32 is bowed, so the substrate surface 32 is planar and at essentially the same level at all points between the first and second STI insulators 20, 22 when the first and second STI insulators 20, 22 are recessed. The STI material 18 may be recessed to a level below the level of the substrate surface 32 with an etchant selective to the STI material 18, such as a wet etch with dilute hydrofluoric acid. In an exemplary embodiment, the first and second STI insulators 20, 22 are recessed to about 10 to about 20 nanometers below the substrate surface 32. A device width (indicated by the double headed arrow 30) is the distance between the first and second STI insulators 20, 22, as measured along the substrate surface 32. At this point, the substrate surface 32 is planar, so the device width 30 is the straight line distance between the first and second STI insulators 20, 22.

Reference is made to the exemplary embodiment in FIG. 4. The substrate 12 is extended with a cap 34 that is epitaxially grown overlying the substrate 12 between the first STI insulator 20 and the second STI insulator 22. Other caps 34 may extend over the substrate on the opposite side of the first and second STI insulators 20, 22, as illustrated, and these other caps 34 may be part of other components of the integrated circuit 10. In this description the adjacent caps 34 are used for production of a transistor, but the caps 34 for adjacent areas are used for other types of electronic components in alternate embodiments. In an exemplary embodiment, the cap 34 is silicon germanium. However, other materials may be used for the cap 34, such as silicon or other semiconductor materials. Silicon germanium can be epitaxially grown by vapor phase epitaxy using silane and germane gas, but other types of epitaxy can also be used, such as molecular beam epitaxy or the like. In an exemplary embodiment, the cap 34 is grown by vapor phase epitaxy using silane and germane at a temperature of from about 700 degrees centigrade (° C.) to about 800° C. over a period of from about 6 hours to about 12 hours. Conductivity determining impurities (“dopants”) of the desired type may be added to the source gas during the epitaxial growth, so the cap 34 is formed with the desired dopant at the desired concentration. In an exemplary embodiment, the cap 34 is from about 5 mole percent germanium to about 50 mole percent germanium, and about 50 mole percent silicon to about 95 mole percent silicon, but in other embodiments the cap 34 is about 99 mole percent or more silicon, or about 20 to about 95 mole percent germanium and about 5 to about 80 mole percent silicon. The cap 34 may also be formed with a concentration gradient, so the concentration changes as the distance from the substrate surface 32 increases.

The cap 34 extends the crystalline structure of the substrate 12, but the first and second STI insulators 20, 22 are not crystalline so the cap 34 does not grow from them. As such, the cap 34 forms over the substrate 12 and along the exposed vertical portion of the substrate 12 in the first and second trenches 14, 16. The cap 34 is formed of substrate material, which may be the same or different than the material in the substrate 12 below the cap 34, so the cap 34 becomes a portion of the substrate 12 as it is formed. The top of the cap 34 becomes the substrate surface 32, because the cap 34 is part of the substrate 12. The cap 34 is not constrained in an enclosed space, so the cap 34 does not have significant crystal lattice strain even in embodiments where the cap 34 includes compounds different than the substrate, such as a substrate 12 underlying the cap 34 with about 99 or more mole percent silicon and a cap 34 with about 25 mole percent germanium.

The cap 34 is formed into a bow shape during the epitaxial growth. Not to be bound by theory, but the cap 34 may form a bowed shape due to the epitaxial loading effect. The cap 34 may extend into the first and second trenches 14, 16 somewhat, but most of the material of the cap 34 is positioned overlying the substrate 12 between the first and second STI insulators 20, 22. The bowed cap 34 has a bow length illustrated by the doubled headed arrow 40, and a bow height illustrated by the double headed arrow 42. In an exemplary embodiment, the bow height 42 is about 10 to about 40 percent of the bow length 40, or the bow height 42 is about 20 to about 30 percent of the bow length 40 in another embodiment. For example, the bow length 40 may be about 80 nanometers, and the bow height 42 may be about 20 nanometers in an embodiment where the bow height 42 is about 25 percent of the bow length 40. The bowed shape of the substrate surface 32 increases the device width 30, because the distance between the first and second STI insulators 20, 22 along the bowed substrate surface 32 is greater than the straight line distance between the first and second STI insulators 20, 22.

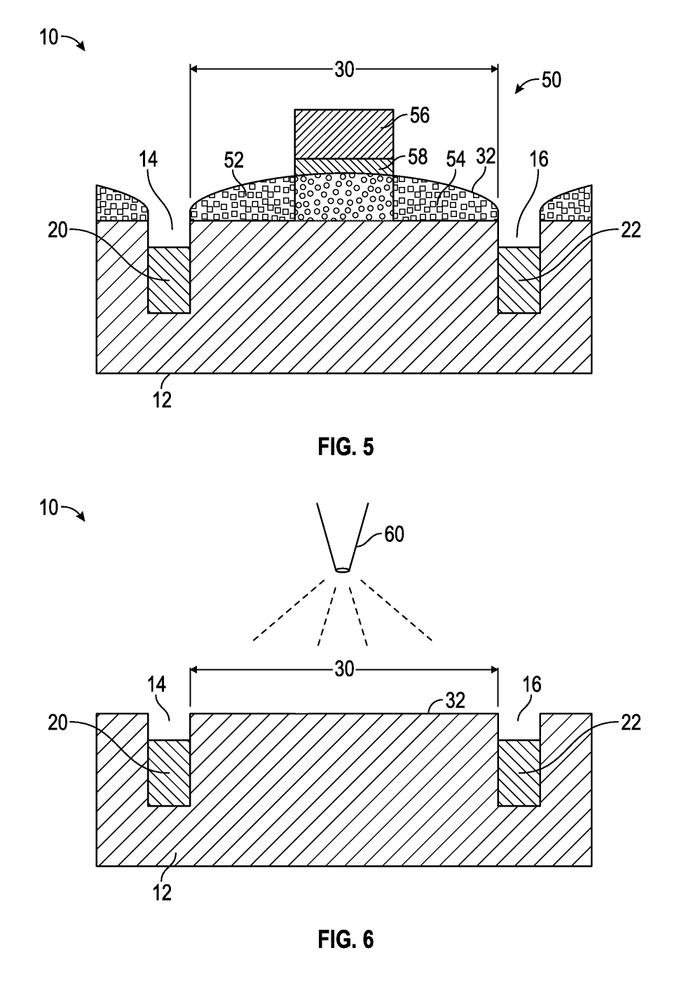

Referring to the exemplary embodiment in FIG. 5, a transistor 50 is formed between the first and second STI insulators 20, 22. The transistor 50 is a field effect transistor (FET) in an exemplary embodiment, and includes a source 52 and a drain 54 formed within the substrate 12 and a gate 56 formed overlying the substrate 12. The source 52 and drain 54 are formed within the substrate 12 with the bowed substrate surface 32, so the source 52 and drain 54 have a curved surface. A gate dielectric 58 is positioned between the gate 56 and the substrate 12 to electrically isolate the gate 56 from the substrate 12. The source 52, drain 54, gate 56, and gate dielectric 58 are formed using methods and techniques well known to those skilled in the art. The transistor 50 is similar to a planar transistor 50, except the substrate surface 32 (which is the surface of the cap 34 after the cap 34 is formed) is bowed instead of planar. The transistor 50 is incorporated into an integrated circuit 10, as understood by those skilled in the art.

Reference is made to the exemplary embodiment in FIG. 6. In an alternate embodiment beginning after the first and second STI insulators 20, 22 are recessed, the substrate surface 32 is melted such that it reflows and forms a bowed shape. There may or may not be a cap in embodiments where the substrate surface 32 is melted. In embodiments where the substrate 12 is monocrystalline silicon, the substrate 12 melts at about 1,400° C. The substrate 12 can be heated to the melting point by exposing it to a gas cluster ion beam, which may be produced from an accelerator 60. Pressurized gas in a gas cluster ion beam is expanded into a vacuum and is directed at a target by the accelerator 60, where the target is the substrate 12. The accelerator 60 produces clusters of atoms that impact the surface of the substrate 12 and produce high localized heat and pressure. However, individual atoms in the cluster do not have sufficient energy to penetrate deep into the target. Therefore, the gas cluster ion beam can melt the substrate surface 32 and cause it to reflow without changing the structure and composition of the substrate 12, except for perhaps at the substrate surface 32. The gas clusters may be formed of argon, oxygen, or other materials in various embodiments, and a thin layer of silicon dioxide may form overlying the substrate 12 if oxygen is used or present. The thin layer of silicon dioxide can be removed with a dilute hydrofluoric acid wash, if present. The top surface of the first and second STI insulators 20, 22 may or may not be melted as well, but the first and second STI insulators 20, 22 resolidify (if they are melted) and continue to function as designed.

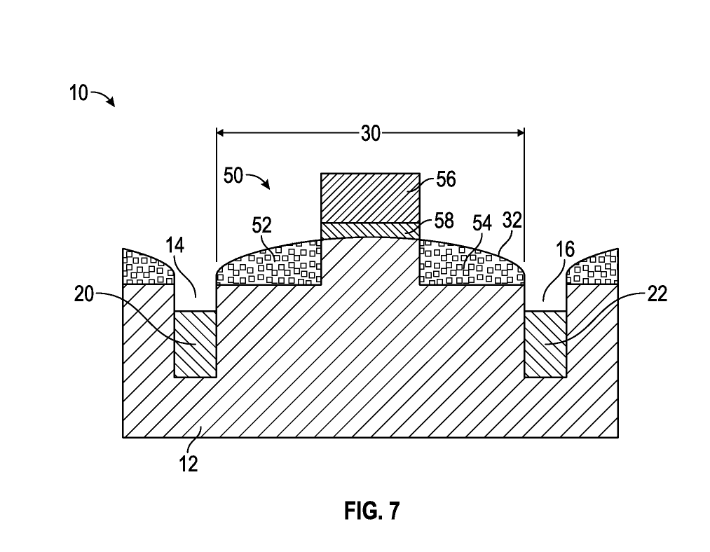

In an exemplary embodiment, the substrate surface 32 melts and reflows into a bow shape, as mentioned above. The bow shape may be due to surface tension or other effects, or it may result from some of the substrate material near the first and second trenches 14, 16 becoming dislodged. The bowed shape increases the device width 30 after the formation of the first and second STI insulators 20, 22, as described above. A transistor 50 is then formed between the first and second STI insulators 20, 22, as described above and as illustrated in FIG. 7, and the transistor 50 is incorporated into an integrated circuit 10 as understood by those skilled in the art.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the application in any way. Rather, the foregoing detailed description will provide those skilled in the art with a convenient road map for implementing one or more embodiments, it being understood that various changes may be made in the function and arrangement of elements described in an exemplary embodiment without departing from the scope, as set forth in the appended claims.

1. A method of manufacturing an integrated circuit comprising:
forming a first STI insulator and a second STI insulator in a substrate:
bowing a substrate surface between the first STI insulator and the second STI insulator; and
forming a transistor between the first STI insulator and the second STI insulator.

2. The method of claim 1 wherein forming the transistor further comprises forming a source and a drain within the substrate between the first STI insulator and the second STI insulator such that the source and the drain have a curved surface.

3. The method of claim 2 wherein forming the transistor comprises forming a gate overlying the substrate between the source and the drain.

4. The method of claim 1 wherein bowing the substrate surface comprises melting the substrate surface.

5. The method of claim 4 wherein bowing the substrate surface comprises melting the substrate surface with a gas cluster ion beam.

6. The method of claim 1 further comprising:
recessing the first STI insulator and the second STI insulator to a level below the substrate surface before bowing the substrate.

7. The method of claim 1 wherein recessing the first STI insulator and the second STI insulator comprises recessing the first STI insulator and the second STI insulator to about 10 to about 20 nanometers below the substrate surface before bowing the substrate.

8. The method of claim 1 wherein bowing the substrate surface comprises exposing the substrate surface to a gas cluster ion beam.

9. The method of claim 1 wherein bowing the substrate surface comprises:
extending the substrate by epitaxially growing a cap of substrate material between the first STI insulator and the second STI insulator, wherein the cap is bowed.

10. The method of claim 9 wherein extending the substrate comprises epitaxially growing the cap of silicon and germanium.

11. The method of claim 9 wherein extending the substrate comprises epitaxially growing the cap of about 99 mole percent or more silicon.

12. The method of claim 1 wherein bowing the substrate comprises bowing the substrate wherein a bow height is about 10 percent to about 40 percent of a bow length.

13. The method of claim 1 wherein bowing the substrate comprises bowing the substrate wherein a bow height is about 20 percent to about 30 percent of a bow length.

14. A method of manufacturing an integrated circuit comprising:
forming a first STI insulator and a second STI insulator in a substrate, wherein a device width is a distance between the first STI insulator and the second STI insulator measured along a substrate surface;
increasing the device width after forming the first STI insulator and the second STI insulator; and
forming a transistor between the first STI insulator and the second STI insulator.

15. The method of claim 14 wherein increasing the device width comprises changing the substrate surface from a planar surface to a non-planar surface.

16. The method of claim 14 wherein increasing the device width comprises melting the substrate surface such that the substrate surface re-flows and forms a non-planar surface.

17. The method of claim 14 wherein increasing the device width comprises:
extending the substrate by epitaxially growing a cap of substrate material, wherein the cap has a bowed shape.

18. The method of claim 14 further comprising:
recessing the first STI insulator and the second STI insulator to a level lower than the substrate surface.

19. The method of claim 14 wherein forming the transistor comprises:
forming a source and a drain within the substrate; and
forming a gate overlying the substrate.

20. An integrated circuit comprising:
a substrate having a substrate surface;
a first STI insulator and a second STI insulator positioned within the substrate, wherein the substrate surface has a bowed shape between the first STI insulator and the second STI insulator; and
a transistor positioned between the first STI insulator and the second STI insulator.
